(19) United States
(12) Patent Application Publication
(10) Pub. No.: US 2024/0128417 A1
(43) Pub. Date: Apr. 18, 2024

(54) METHOD FOR PRODUCING A PLURALITY OF COMPONENTS HAVING HYBRID REFLECTORS AND COMPONENT HAVING HYBRID REFLECTOR

(71) Applicant: ams-OSRAM International GmbH, Regensburg (DE)

(72) Inventors: Khai Loon CHAN, Balik Pulau (MY); Kean Khuan KOO, Sungai Petani (MY); Mohd Fauzi ZAINORDIN, Penang (MY); Tsu Pin CHNG, Georgetown (MY)

(21) Appl. No.: 18/278,360

(22) PCT Filed: Feb. 25, 2021
(86) PCT No.: PCT/EP2021/054697

§ 371 Date: Aug. 22, 2023

(51) Int. Cl. H01L 33/60; H01L 33/52

(52) U.S. Cl. CPC H01L 33/60; H01L 33/52; H01L 2933/005; H01L 2933/0058

(57) ABSTRACT

A method for producing a plurality of optoelectronic components (10) having hybrid reflectors (6) using a single pass dispensing concept is provided, wherein the method comprises:
providing a plurality of semiconductor chips (1) arranged in a plurality of openings (32) of a housing structure (30), wherein the housing structure (30) has elevated parts (31) which vertically project beyond the semiconductor chips (1) and form a first dam structure having parallel columns of first disconnected dams (61), wherein in a top view, the first disconnected dams of the same column are spatially separated by intermediate spaces (6Z); and
forming a second dam structure having parallel second continuous dams (62) using the single pass dispensing concept, wherein the second continuous dams (62) fill the intermediate spaces (6Z) between the first disconnected dams (61) and thereby adjoin the first disconnected dams (61) for forming the hybrid reflectors (6) of the optoelectronic components (10).

Furthermore, an optoelectronic component (10) is provided, wherein the optoelectronic component (10) can be produced according to the method mentioned above.

This disclosure relates to a method for producing a plurality of optoelectronic components having hybrid reflectors as well as to an optoelectronic component having a hybrid reflector.

Using a so-called two pass dispensing concept for forming a plurality of reflectors for a plurality of optoelectronic components, after forming first parallel dams during a first pass dispensing, second dams orthogonal to the first dams may be formed during a second pass dispensing. For avoiding intersection bulging which may lead to bad dam intersection resulting in undesired reflector profile and lower product color yield, during the second pass, the forming of second dams needs to be constantly interrupted. In other words, using the two pass reflector dispensing concept, the process is constantly interrupted with cyclic cycle of ramping up and ramping down the pumping process for avoiding bulging at dam intersections. This may result in a low dam output, high variations in the dam height, non-linear reflector profile and lowered product color yield.

Moreover, the accuracy of dam dispensing is highly dependent on the accuracy of pump positioning. Thus, the process of ramping up and ramping down the dispensing pump may have negative effects on defining light-emitting surfaces of the optoelectronic components, and the second dams have to be kept at a sufficient large distance from chip surfaces.

One object is to provide an efficient and simplified method for producing a plurality of optoelectronic components having reflectors. Another object is to provide a mechanically stable optoelectronic component having well defined light-emitting surface and improved color yield.

These objects are solved by the method for producing a plurality of optoelectronic components having hybrid reflectors and by the optoelectronic component having a hybrid reflector according to the independent claims. Further embodiments of the method and of the optoelectronic component are the subject matter of the further claims.

According to at least one embodiment of the method, for forming a plurality of hybrid reflectors for a plurality of optoelectronic components, a single pass dispensing concept is applied. In particular, a dam structure having parallel continuous dams is formed by a single dispensing process. Each of the continuous dams can be completed with one single pass of continuous dispensing without the need of constantly starting and stopping the dispensing process. For instance, within the production tolerances, the continuous dams can be formed to have the same height and/or the same width. After forming the continuous dams, they can be singulated along singulating lines extending parallel to the continuous dams, for example cut into two halves, wherein each half can form sidewalls of adjacent hybrid reflectors for a plurality of optoelectronic components.

Using one pass dispensing concept, two first opposite sidewalls of each of the hybrid reflectors can be prepared or prefabricated, for example pre-molded or using any other appropriate process, for instance by providing a first dam structure having parallel columns of first disconnected dams. The two remaining second opposite sidewalls of each of the hybrid reflector can be formed from a second dam structure having parallel second continuous dams in particular using the one pass dispensing concept. Forming two or several parallel second continuous dams in combination with the use of prefabricated first disconnected dams, a plurality of hybrid reflectors for a plurality of optoelectronic components can be formed in a very efficient manner, namely by using only one pass motion. This saves production time. Moreover, the hybrid reflectors formed from the first disconnected dams and the second continuous dams show less variations in their geometrical sizes or geometrical shapes. Thus, the uniformity of hybrid reflectors or the uniformity of light-emitting surfaces or the color quality of the optoelectronic components is much higher compared to the case of using for instance a two pass dispensing concept for forming the reflectors. Also the so-called package yield is more predictable compared with the case of using two pass dispensing concept.

A manufacturing method using a single pass dispensing concept or a one pass dispensing concept for producing hybrid reflectors can be understood to mean a method using only one single dispensing step in particular for forming dams or sidewalls of the hybrid reflectors. After performing the only one dispensing step, further method steps different from the dispensing step may apply, for example for singulating the hybrid reflectors, but no further dispensing step for forming the hybrid reflectors is required or intended.

In at least one embodiment of a method for producing a plurality of optoelectronic components having hybrid reflectors, a single pass dispensing concept is used. According to this method, a plurality of semiconductor chips arranged in a plurality of openings of a housing structure is provided. The housing structure has elevated parts which vertically project beyond the semiconductor chips and form a first dam structure having parallel columns of first disconnected dams. In top view, the first disconnected dams of the same column are spatially, in particular laterally separated by intermediate spaces. A second dam structure is formed using the single pass dispensing concept, wherein the second dam structure has parallel second continuous dams. The second continuous dams fill the intermediate spaces between the first disconnected dams and thereby adjoin the first disconnected dams for forming the hybrid reflectors of the optoelectronic components.

A vertical direction is understood to mean a direction which is directed perpendicular to a front side or to a rear side of the semiconductor chip or of the optoelectronic component. A lateral direction is understood to mean a direction which is parallel to a front side or to a rear side of the semiconductor chip or of the optoelectronic component. The vertical direction and the lateral direction are orthogonal to each other.

The first disconnected dams and the second continuous dams are for instance orthogonal or substantially orthogonal to each other. By filling the intermediate spaces, the second continuous dams can directly adjoin the first disconnected dams. For example, in top view, within the production tolerances, the second continuous dams do not cover the first disconnected dams. Thus, the second continuous dams and the first disconnected dams together form in particular a netlike structure with no bulging at intersection points.

According to at least one embodiment of the method, the first disconnected dams and the remaining part of the housing structure are formed in one piece. In other words, the housing structure comprising the first disconnected dams is made of a single piece. For example, the housing structure does not comprise separate parts connected to each other for instance using a connecting material. The housing structure rather comprises only integral parts integrally connected with each other, i.e. without using any additional connecting material. Such integral parts can be formed from the same material. In particular, the first disconnected dams and the remaining part of the housing structure are made of the same material. In this case, however, it is possible that the first disconnected dams are additionally coated with a reflective material, for example with a TiO2-containing material. Hence, if the first disconnected dams are additionally coated with a reflective material, compared to the material of the remaining part of the housing structure, they can still be considered as being made of a common or of the same material. If the housing structure is singulated in a plurality of housings, each of the singulated housing can be of one piece form. The housing or the housing structure can be made of a molding material.

According to at least one embodiment of the method, before providing the housing structure, the first disconnected dams and the remaining part of the housing structure are formed during a common manufacturing process. Such common manufacturing process may be a molding or casting process or other process.

According to at least one embodiment of the method, the first disconnected dams and the remaining part of the housing structure are made of different materials. For example, before providing the housing structure, the first disconnected dams and the remaining part of the housing structure are formed in two different manufacturing processes. In deviation from this, it is possible for the first disconnected dams and the remaining part of the housing structure to be made of the same material, even if they are formed in two different manufacturing processes. The first disconnected dams can be formed or fixed on the remaining part of the housing structure. In this case, the first disconnected dams can be mechanically or chemically connected to the remaining part of the housing structure, after the remaining part of the housing structure has been formed. The first disconnected dams can be coated with a reflective material.

According to at least one embodiment of the method, the second continuous dams are made of the same material. The material of the second continuous dams can differ from the material of the first disconnected dams. It is, however, also possible, that second continuous dams and the first disconnected dams are made of identical material.

According to at least one embodiment of the method, the first disconnected dams and the second continuous dams are directly adjacent to each other but do not overlap each other. A first disconnected dam and a second continuous dam do not overlap each other if for instance at intersection points, the second continuous dam is not arranged on top of the first disconnected dam, or vice versa. It is, however, possible that due to production tolerances, the second continuous dam directly adjoins and slightly covers a small part of the first disconnected dam.

According to at least one embodiment of the method, in lateral directions, the housing structure surrounds a lead frame structure which is configured for electrically contacting the plurality of semiconductor chips. In vertical direction, the housing structure can be arranged in places on the lead frame structure and partially covers a front side of the lead frame structure. For example, a rear side of the lead frame structure is not covered by the housing structure.

The lead frame structure can comprise a plurality of lead frames, wherein each lead frame can be assigned to one semiconductor chip or to one optoelectronic component. Each lead frame can comprise a first subregion and a second subregion assigned to different electrical polarities of the semiconductor chip or of the optoelectronic component. The first subregion and the second subregion of the lead frame are laterally separated from each other and can be mechanically connected to each other by a material of the housing or of the housing structure. The semiconductor chip can be arranged on the first subregion of the lead frame and can be electrically connected to the first subregion of the lead frame using an electrically conductive connection layer.

Using a wiring structure, for example a wiring connection such as a bond wire, the semiconductor chip can be electrically connected to the second subregion of the lead frame.

According to at least one embodiment of the method, each of the semiconductor chips are electrically connected to a wiring structure, wherein the wiring structure is covered by the second continuous dams but not by the first disconnected dams. For instance, the wiring structure assigned to each of the semiconductor chips comprises a first wiring connection which is configured to electrically connect the semiconductor chip to a subregion of the lead frame. The wiring structure can comprise a second wiring connection which is configured to electrically connect a protective diode, for instance an ESD diode, to a subregion of the lead frame. It is possible that the protective diode is formed as an integral part of the semiconductor chip or differs from the semiconductor chip.

According to at least one embodiment of the method, the optoelectronic components are singulated along singulating lines throughout the first disconnected dams and/or throughout the second continuous dams. For example, cutting along one singulating line parallel to one first disconnected dam, the first disconnected dam is singulated into two halves with the same length but substantially only half of the original width. At the intersection points, each of the second continuous dams may be cut into two pieces with the same width but different lengths. Cutting along one singulating line parallel to the second continuous dam, however, only the second continuous dam is singulated into two halves with the same length but substantially only half of the original width.

After singulating, each of the singulated optoelectronic components has a hybrid reflector surrounding one of the semiconductor chips, wherein the hybrid reflector is formed by singulated parts of the first disconnected dams and of the second continuous dams. In particular, the hybrid reflector comprises two first opposite sidewalls and two second opposite sidewalls, wherein the first opposite sidewalls arise from two parallel singulated first disconnected dams and the second opposite sidewalls arise from two parallel singulated second continuous dams.

During the singulating process, the housing structure is singulated into a plurality of housings and the lead frame structure is singulated into a plurality of lead frames. Each of the optoelectronic components can comprise a housing and a lead frame having a first subregion and a second region. The housing comprises an opening in which the semiconductor chip is arranged. The semiconductor chip is electrically connected to the lead frame. In particular, the housing and the lead frame arise from singulating the housing structure and the lead frame structure along the singulating lines, respectively.

In the following, in particular a singulated optoelectronic component is specified.

In an embodiment of an optoelectronic component, it comprises a semiconductor chip, a housing and a hybrid reflector, wherein the semiconductor chip is arranged in an opening of the housing. The hybrid reflector vertically projects beyond the semiconductor chip and in a top view surrounds the semiconductor chip. The hybrid reflector comprises two first opposite sidewalls and two second opposite sidewalls, wherein the first sidewalls directly adjoin the second sidewalls at interfaces which are formed exclusively by overlapping regions of inner side surfaces of the first sidewalls and of the second sidewalls.

In particular, the first sidewalls are elevated parts of the housing and are made of the same material which is different from a material of the second sidewalls. It is, however, possible that the first sidewalls and the second sidewalls are made of identical material.

Such an optoelectronic component having the hybrid reflector can be produced by a method using the one pass dispensing concept described in this disclosure. Thus, features and advantages described in connection with the method can be used for the optoelectronic component, and vice versa.

According to at least one embodiment, the optoelectronic component is a Quad Flat No-Lead, QFN, optoelectronic component, whose side surfaces are formed at least partly by side surfaces of the housing, wherein the optoelectronic component is free of electrical connections or pins projecting laterally beyond the side surfaces of the housing. In particular, the QFN optoelectronic component is free of electrical connections or pins projecting laterally beyond its entire side surfaces.

In this case, however, it is possible that the component has metal structures on its side surfaces. These metal structures may be singulated connecting arms, wherein the connecting arms are used to connect neighboring lead frames of the lead frame structure and thus mechanically stabilize the lead frame structure during the production of the optoelectronic components. Such metal structures, however, do not project laterally beyond the side surfaces of the housing or of the optoelectronic component. The metal structures or singulated connecting arms are rather flush with the side surfaces of the housing and thus partly form the side surfaces of the optoelectronic component. The metal structures or singulated connecting arms may show singulating traces on the side surfaces of the optoelectronic component.

According to at least one embodiment of the optoelectronic component, it comprises side surfaces which are formed partly by side surfaces of the housing and partly by outer side surfaces of the first sidewalls and of the second sidewalls. In particular, the side surfaces of the housing and the outer side surfaces of the sidewalls show singulating traces.

According to at least one embodiment of the optoelectronic component, the first sidewalls and the remaining part of the housing are formed in one piece and are made of the same material. When the first sidewalls and remaining part of the housing are made of the same material, it is still possible that the first sidewalls are additionally coated with a reflective material. Here, the reflective material is not considered as a material of the first sidewalls but rather as a material of a coating layer applied on the first sidewalls.

According to at least one embodiment of the optoelectronic component, the first sidewalls are arranged on the remaining part of the housing, wherein the material of the first sidewalls differs from a material of the remaining part of the housing. In particular, the first sidewalls and the remaining part of the housing are not formed in one piece. The first sidewalls are rather formed or fixed on the remaining part of the housing, after the remaining part of the housing has been formed. Thus, there are connecting surfaces between the first sidewalls and the remaining part of the housing.

According to at least one embodiment of the optoelectronic component, it further comprises a lead frame, wherein the lead frame comprises a first subregion and a second subregion. The first and second subregions are assigned to different electrical polarities of the optoelectronic component. The semiconductor chip is arranged on the first subregion of the lead frame. The semiconductor chip is electrically connected to the second subregion by a wiring connection, wherein the wiring connection is partly embedded within one of the second sidewalls.

According to at least one embodiment of the optoelectronic component, it is formed as a surface-mountable device, wherein the optoelectronic component is externally electrically contactable at its rear side, where the first and second subregions of the lead frame are not covered by a material of the housing.

According to at least one embodiment of the optoelectronic component, the semiconductor chip is laterally surrounded by a reflective layer. In a plan view of a front side of the component, the reflective layer is arranged in particular between the semiconductor chip and the housing. In a plan view of a front side of the component, the reflective layer can be partially covered by the second sidewalls but, for example, is not covered by the first sidewalls of the hybrid reflector.

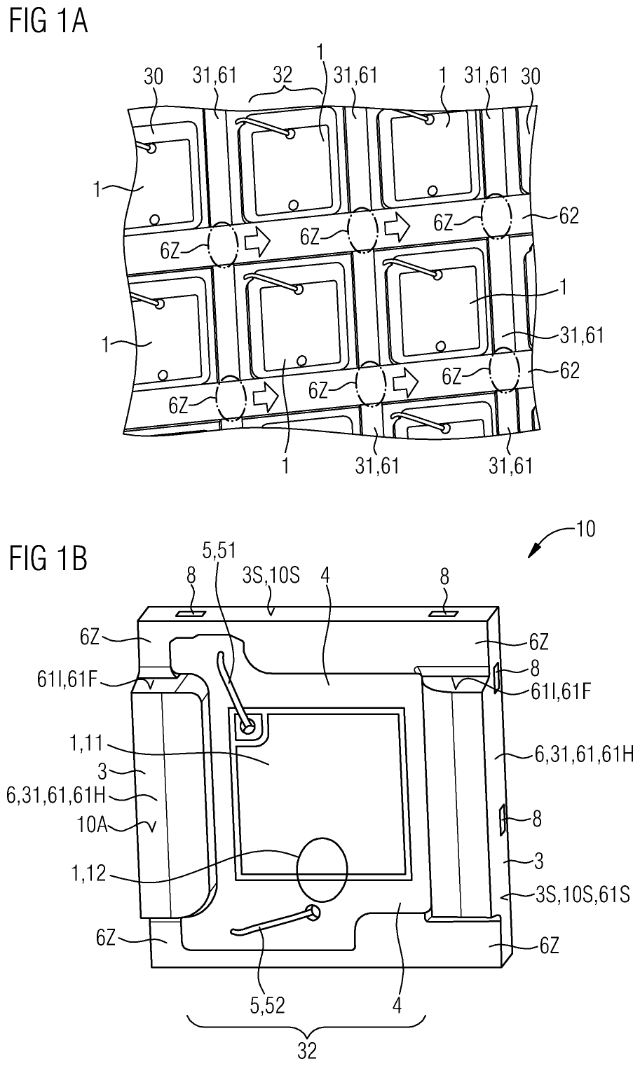

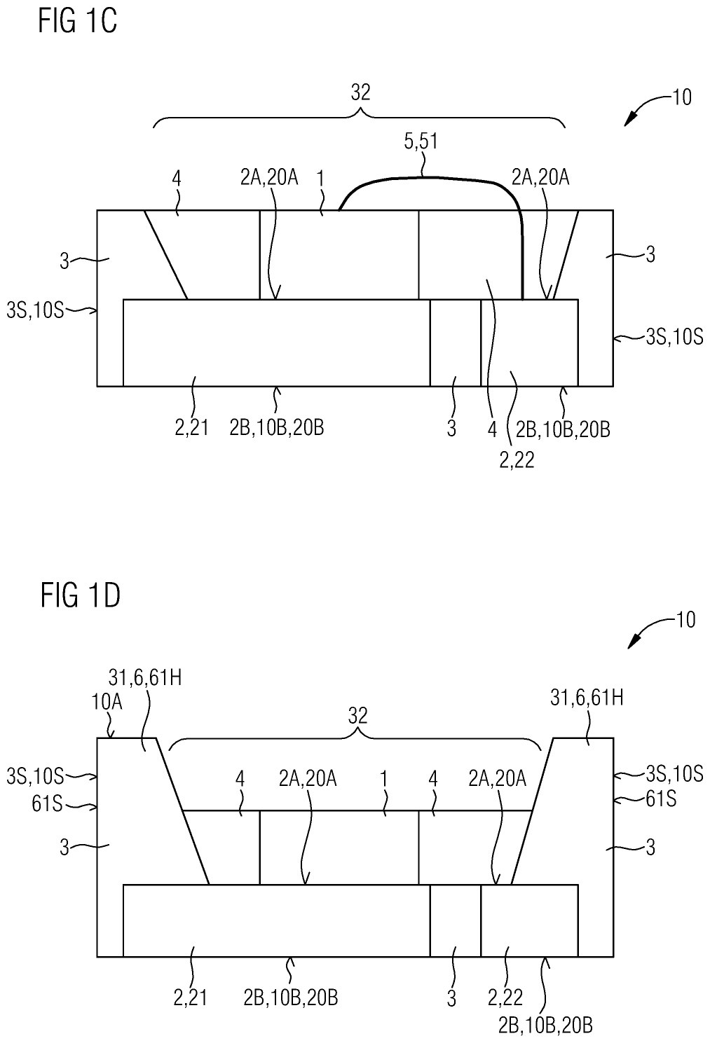

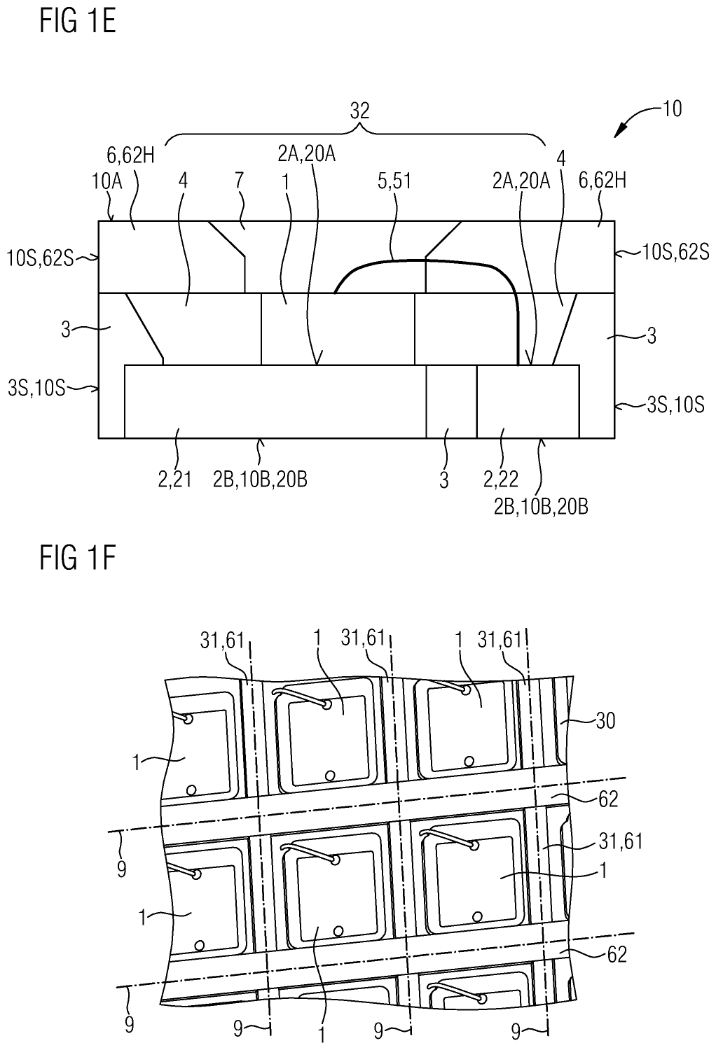

Further advantages and developments of the method or of the component will become apparent from the exemplary embodiments explained below in conjunction with FIGS. 1A to 3.

FIG. 1A shows a schematic illustration of the one pass dispensing concept.

FIGS. 1B, 1C, 1D and 1E show some schematic illustrations of the component in sectional views and in a 3-dimensional view.

FIG. 1F shows a schematic illustration of a singulating step of the method.

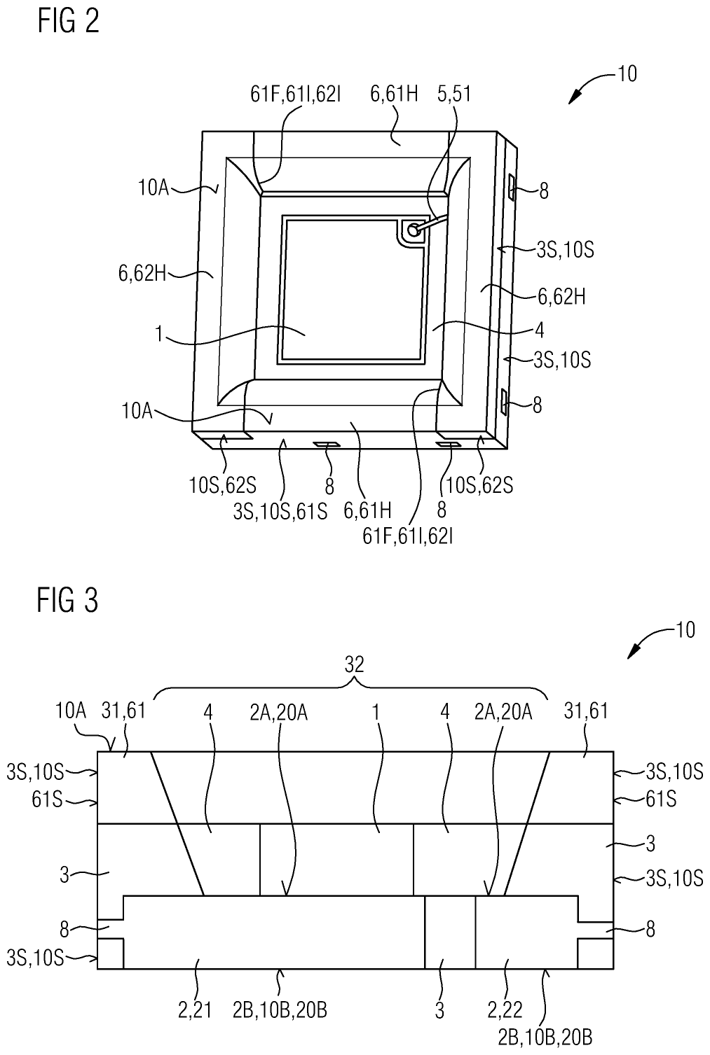

FIGS. 2 and 3 show some further schematic illustrations of the component.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

FIG. 1A shows a schematic illustration of the one pass dispensing concept, according to which hybrid reflectors 6 for a plurality of optoelectronic components 10 can be formed using a dispensing process in one pass motion only. The dispensing process in one pass motion is performed for forming a dam structure having parallel continuous dams 62 shown in FIG. 1A.

Without the continuous dams 62, the remaining structure shown in FIG. 1A can be prefabricated, before the single pass dispensing concept is applied.

According to this method, a plurality of semiconductor chips 1 arranged in a plurality of openings 32 of a housing structure 30 is provided. The housing structure 30 is for instance a mold body. The semiconductor chips 1 are for example light-emitting diodes. The semiconductor chips 1 or the openings 32 are arranged in a matrix form comprising a plurality of rows and columns.

The housing structure 30 comprises a first dam structure having parallel columns of first disconnected dams 61. The first disconnected dams 61 are formed by elevated parts 31 of the housing structure 30 which project vertically beyond the semiconductor chips 1. The elevated parts 31 may be integral parts of the housing structure 30 which are formed in one piece with the remaining part of the housing structure 30. The elevated parts 31 and the remaining part of the housing structure 30 may be formed of the same material. It is possible that only the elevated parts 31 of the housing structure 30 is additionally coated with a reflective material. In deviation from this, it is also possible that the elevated parts 31 are subsequently formed or fixed on the remaining part of the housing structure 30. In this case, the elevated parts 31 and the remaining part of the housing structure 30 may be formed from different materials.

Besides the peripheral first disconnected dams 61, the first disconnected dams 61 are arranged between two columns of the semiconductor chips 1. As indicated in FIG. 1A, the first disconnected dams 61 of the same column are spatially separated by intermediate spaces 6Z. In other words, the intermediate spaces 6Z are not filled with material of the first disconnected dams 61. This is shown explicitly for instance in FIG. 1B.

According to the one pass dispensing concept, a second dam structure comprising parallel second continuous dams 62 is formed using a single pass dispensing process, wherein the second continuous dams 62 fill and connect the intermediate spaces 6Z between the first disconnected dams 61. In particular only at intermediate spaces 6Z, i.e. at the intersection points between the second continuous dams 62 and the first disconnected dams 61, the second continuous dams 62 directly adjoin the first disconnected dams 61. In a plan view, each of the semiconductor chips 1 is completely surrounded by a combination of the second continuous dams 62 and the first disconnected dams 61.

Thus, for example, after completing a wire bonding process, a dispensing weight and a dispensing speed are controlled in particular along wire-bonding directions to form the second continuous dams 62 and thus to form completely enclosed hybrid reflectors 6. By performing this process, in particular squared light-emitting surfaces within the enclosed hybrid reflectors 6 are defined. According to this method, the process of dispensing is performed continuously along one axis or along parallel axes. Hence, the pumping of dispensing material does not need to start and stop over and over again. This results in a high number of components 10 which can be produced within a predetermined production time.

After singulating, each of the singulated optoelectronic components 10 comprises a hybrid reflector 6 made of parts of the second continuous dams 62 and of the first disconnected dams 61. In particular, the hybrid reflector 6 is formed from singulated parts of exactly two first disconnected dams 61 and two second continuous dams 62. The disconnected dams 61 and the continuous dams 62 can be made of different materials and/or can have different degrees of reflectivity.

FIG. 1B shows a schematic illustration of the component 10 without the singulated parts of the continuous dams 62. The singulated parts of the continuous dams 62 are not shown in FIG. 1B in particular for reasons of simplicity. Thus, the component 10 shown in FIG. 1B can also be seen as a subregion of the structure shown in FIG. 1A before the second continuous dams 62 are applied, wherein this subregion defines the size of one optoelectronic component 10 to be produced.

According to FIG. 1B, the component 10 comprises one semiconductor chip 1, a housing 3 and two first opposite sidewalls 61H of a hybrid reflector 6. The semiconductor chip 1 is arranged in an opening 32 of the housing 3. The semiconductor chip 1 is laterally spaced apart from the hybrid reflector 6 and is laterally surrounded by a reflective layer 4. It is possible that the reflective layer 4 and a coating layer on the first disconnected dams 61 are made of the same material. For example, after completing a wire bonding process, TiO2 may be jetted into the openings 32 and on top of the first disconnected dams 61, in particular on slanted surfaces the first disconnected dams 61 facing light-emitting surfaces of the semiconductor chips 1.

In FIG. 1B, only about half of the disconnected dam 61 is shown on the right edge or on left edge of the component 10. This half of the disconnected dam 61 forms one of the first two opposite sidewalls 61H of the hybrid reflector 6. The first two opposite sidewalls 61H are in particular integral parts of the housing 3 and can be made of the same material as the housing 3.

A top surface of the first sidewall 61H can form one part of a front side 10A of the component 10. An outer surface 61S of the first sidewall 61H can form one part of one side surface 3S of the housing 3 and thus form one part of one side surface 10S of the component 10. An inner side surface 61I of the first sidewall 61H can form an interface 61F which is a common interface or a connecting surface between the first sidewall 61H and the second sidewall 62H. The interface 61F can be flat or curved, or partially flat and partially curved.

The component 10 has a the wiring structure 5, wherein the semiconductor chip 1 can be electrically connected to one subregion 22 of a lead frame 2 as shown for instance in FIGS. 1C and 1D. FIGS. 1C and 1D show two sectional views of the component 10 shown for instance in FIG. 1B.

As shown in FIGS. 1C and 1D, the lead frame 2 comprises a first subregion 21 and a second subregion 22, wherein the first subregion 21 and the second subregion 22 are assigned to different electrical polarities of the optoelectronic component 10. The first subregion 21 and the second subregion 22 are laterally separated and are mechanically connected to each other by material of the housing 3. In lateral directions, the lead frame 2 comprising the first subregion 21 and the second subregion 22 can be surrounded, for instance completely surrounded by the housing 3. In top view, the housing 3 can partly cover the first subregion 21 and/or the second subregion 22 of the lead frame 2 as shown for instance in FIGS. 1C and 1D.

Each semiconductor chip 1 can be assigned to exactly one lead frame 2, and vice versa. Before singulating, the lead frames 2 form a lead frame structure 20. The first subregions 21 and second subregions 22 of different lead frames 2 can be connected to each other by connecting arms 8 during the process of producing the plurality of optoelectronic components 10. Such connecting arms 8 are shown schematically on side surfaces 3S of the housing 3 or on side surfaces 10S of the component 10 (see also FIG. 3).

The connecting arms 8 are used to connect neighboring lead frames 2 of the lead frame structure 20 and can mechanically stabilize the lead frame structure 20 during the production of the optoelectronic components 10 or during the production of the housing structure 30. For facilitating the process of singulating, the connecting arms 8 can have a cross section which for instance is at least five times, for example at least ten times or at least 15 times smaller than an associated cross section of the corresponding subsection 21 or 22 of the lead frame 2. During the singulation of the components 10, the connecting arms 8 are severed, for example sawn through, and can show singulating traces on side surfaces 10S of the components 10. Outer surfaces of the singulated connecting arms 8 are flush with side surfaces 3S of the housing 3 and thus do not laterally project beyond the side surfaces 3S of the housing 3.

The semiconductor chip 1 is arranged on the first subregion 21 of the lead frame 2 can be electrically connected to the first subregion 21 directly or via an electrically conductive connection layer. The semiconductor chip 1 is electrically connected to the second subregion 22 by a wiring connection 51 of the wiring structure 5. The wiring connection 51 can be partly embedded in the reflective layer 4 as shown in FIG. 1C.

As shown in FIG. 1B, the wiring structure 5 can comprise a further wiring connection 52. For example, the further wiring connection 52 is configured to electrically connect a protective diode, for instance an ESD diode, to the subregion 22 or 21 of the lead frame 2. It is possible that the protective diode is formed as an integral part of the semiconductor chip 1. For instance, the semiconductor chip 1 comprises a light-emitting region 11 and a protective region 12 as indicated in FIG. 1B. The light-emitting region 11 and the protective region 12 can be formed by two semiconductor layer sequences of the semiconductor chip 1 which can be electrically connected to each other in an anti-parallel manner using the wiring connection 51 and the further wiring connection 52. As an alternative, it is possible that the protective diode is not part of the semiconductor chip 1 and can be electrically connected to the semiconductor chip 1 in an anti-parallel manner.

As shown in FIG. 1B, the wiring structure 5 is not embedded within the first sidewalls 61H. In particular, in top view, the wiring connection 51 and/or the further wiring connection 52 are/is not covered by the first sidewalls 61H. In top view, the wiring structure 5 comprising the wiring connection 51 and/or the further wiring connection 52 can be located partially in the intermediate spaces 6Z between the first disconnected dams 61 or in regions located between the intermediate spaces 6Z which are filled by material of the second continuous dams 62 for forming the second sidewalls 62H of the hybrid reflector 6. Hence, it is possible that the wiring structure 5 is covered only by the second continuous dams 62 but not by the first disconnected dams 61. In this case, the wiring structure 5 comprising the wiring connection 51 and/or the further wiring connection 52 is partly embedded within the second sidewall/s 62H as shown for instance in FIG. 1E showing another sectional view of the component 10 having the second sidewall/s 62H of the hybrid reflector 6.

In FIG. 1E, the second sidewalls 62H of the hybrid reflector 6 are shown. The second sidewalls 62H have a lateral width which is about half of the width of the corresponding second continuous dams 61. The second sidewalls 62H are located on two opposite edges of the housing 3. In top view, a lateral distance between the second sidewalls 62H and the semiconductor chip 1 or between the second sidewalls 62H and a light-emitting surface of the semiconductor chip 1 can be less than 100 μm, for instance less than 70 μm or less than 50 μm. This small distance can be realized in a simplified manner using the one pass dispensing concept.

Using this concept, there are more flexibility in forming and designing the first sidewalls 61H, which are formed for instance by pre-molded structures. Moreover, the second sidewalls 62H can be easily tailored to follow the profile of the first sidewalls 61H. Since the first sidewalls 61H is pre-fabricated, a lateral distance between the first sidewalls 61H and the semiconductor chip 1 or between the first sidewalls 61H and the light-emitting surface of the semiconductor chip 1 can be also less than 100 μm, for instance less than 70 μm or less than 50 μm.

As shown in FIG. 1E and also in FIGS. 1C and 1D, the semiconductor chip 1 is arranged on a front side 2A of the lead frame 2, in particular on a front side of the first subregion 21 of the lead frame 2. The semiconductor chip 1 is laterally surround by the reflective layer 4. In a plan view of a front side 10A of the component 10, the reflective layer 4 is partially covered by the second sidewalls 62H but is not covered by the first sidewalls 61H of the hybrid reflector 6 (see also FIGS. 1C and 1D).

Before singulating, the semiconductor chips 1 located in the openings 32 are arranged on a front side 20A of the lead frame structure 20. Along vertical direction, the subregions 21 and 22 of the lead frame 2 extend throughout the housing 3 or the housing structure 30. Thus, the rear side 2B of the lead frame 2 or the rear side 20B of the lead frame structure is not covered by a material of the housing 3. Hence, the component 10 can be formed as a surface-mountable device and can be externally electrically contactable at its rear side 10B. In particular, the rear side 10B of the component 10 is partially formed by the rear side 2B of the lead frame 2 and partially formed by a rear side of the housing 3.

The side surfaces 10S of the optoelectronic component 10 can be formed partially by outer side surfaces 62S of the second sidewalls 62H and side surfaces 3S of the housing 3 including outer side surfaces 61S of the first sidewalls 61H. The side surfaces 10S of the optoelectronic component 10 can also comprise side surfaces of the singulated connecting arms 8. It is possible that any subarea of the side surfaces 10S shows singulating traces.

As shown in FIG. 1E, the hybrid reflector 6 can be filled with an encapsulation layer 7. The encapsulation layer 7 is formed for example from a radiation transmissive material. The front side 10A of the optoelectronic component 10A can be formed in places by surfaces of the encapsulation layer 7, top surfaces of the first sidewalls 61H and top surfaces of the second sidewalls 62H.

According to FIG. 1F, the optoelectronic components 10 can be singulated along singulating lines 9. Singulating along one singulating line 9 parallel to the first disconnected dams 61 of the same column, each of the first disconnected dams 61 of the same column is singulated into two halves with the same length but substantially only half of the original width. At the intersection points between the first disconnected dams 61 and the second continuous dams 62, each of the second continuous dams 62 is cut into two pieces with the same width but different lengths. Singulating along one singulating line parallel to the second continuous dam 62, only the second continuous dam 62 is singulated into two halves with the same length but substantially only half of the original width.

Thus, each singulated component 10, as shown for instance in FIGS. 1B to 1E and also in FIGS. 2 and 3, is defined by a region delimited by four singulating lines 9 intersecting at four adjacent intermediate spaces 6Z. A three-dimensional illustration of such a component 10 is shown in FIG. 2, wherein the encapsulation layer 7 is not shown in FIG. 2 in particular for reasons of simplicity.

The component 10 shown in FIG. 2 comprises a hybrid reflector 6, wherein the hybrid reflector 6 comprises two first opposite sidewalls 61H and two second opposite sidewalls 62H. The first sidewalls 61H directly adjoin the second sidewalls 62H at four interfaces 61F which are formed exclusively by overlapping regions of inner side surfaces 61I of the first sidewalls 61H and inner side surfaces 62I of the second sidewalls 62H. The four interfaces 61F are located at four corners of the hybrid reflector 6.

As indicated in FIG. 2, the wiring structure 5 is partly embedded within the second sidewalls 62H. In particular, one of the opposite second sidewalls 62H can partly cover the wiring connection 51. The other of the opposite second sidewalls 62H can partly or completely cover the further wiring connection 52 which is therefore not shown in FIG. 2.

FIGS. 1D and 1E substantially show to sectional views of the component 10 shown in FIG. 2. Thus, features described in connection with FIGS. 1D and 1E can be also used for the optoelectronic component 10 shown in FIG. 2, and vice versa.

The sectional view of a component illustrated in FIG. 3 corresponds substantially to the sectional view of a component illustrated in FIG. 1D. In contrast to this, in FIG. 3, the encapsulation layer 7 and the connecting arms 8 or the singulated connecting arms 8 are shown explicitly. Furthermore, in contrast to FIG. 1D, in FIG. 3, it is indicated that the elevated parts 31 or the first sidewalls 61H are formed or fixed on the remaining part of the housing 3. In this sense, the first sidewalls 61H and the remaining part of the housing 3 are not formed in one piece manner. The first sidewalls 61H and the remaining part of the housing 3 may be formed from the same material or of different materials.

So far, forming dam-reflector using two pass dispensing concept is one feasible way for forming wire-bonded package which further minimizes the package size of a component formed as a Chip Size Package (CSP). Using the one pass dispensing concept, however, many improvements with regard to package color quality, uniformity of the components or production cost can be achieved.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the patent claims or exemplary embodiments.

### REFERENCES

10 optoelectronic component
10A front side of the optoelectronic component
10B rear side of the optoelectronic component
10S side surface of the optoelectronic component
1 semiconductor chip
11 light-emitting region
12 protective region
2 lead frame
2A front side of the lead frame
2B rear side of the lead frame
20 lead frame structure
20A front side of the lead frame structure
20B rear side of the lead frame structure
21 first subregion of the lead frame
22 second subregion of the lead frame
3 housing of the optoelectronic component
3S side surface of the housing
30 housing structure
31 elevated part of the housing/housing structure
32 opening of the housing/housing structure
4 reflective layer
5 wiring structure
51 wiring connection
52 further wiring connection
6 hybrid reflector
61 first disconnected dam
6Z intermediate spaces between the first disconnected dams
61H first sidewall of the hybrid reflector
61I inner side surface of the first sidewall
61S outer side surface of the first sidewall
61F interface
62 second continuous dam
62H second sidewall of the hybrid reflector
62I inner side surface of the second sidewall
62S outer side surface of the second sidewall
7 encapsulation layer
8 connecting arm
9 singulating line

1. A method for producing a plurality of optoelectronic components having hybrid reflectors using a single pass dispensing concept, the method comprising:
providing a plurality of semiconductor chips arranged in a plurality of openings of a housing structure, wherein the housing structure has elevated parts which vertically project beyond the semiconductor chips and form a first dam structure having parallel columns of first disconnected dams, wherein in a top view, the first disconnected dams of the same column are spatially separated by intermediate spaces; and
forming a second dam structure having parallel second continuous dams using the single pass dispensing concept, wherein the second continuous dams fill the intermediate spaces between the first disconnected dams and thereby adjoin the first disconnected dams for forming the hybrid reflectors of the optoelectronic components.

2. The method according to claim 1,
wherein the second dam structure having parallel second continuous dams is formed by a dispensing process and each of the second continuous dams is completed with one single pass of continuous dispensing without the need of constantly starting and stopping the dispensing process.

3. The method according to claim 1,
wherein the first disconnected dams and the remaining part of the housing structure are formed in one piece and are made of the same material.

4. The method according to claim 3,
wherein before providing the housing structure, the first disconnected dams and the remaining part of the housing structure are formed during a common manufacturing process.

5. The method according to claim 1,
wherein the first disconnected dams and the remaining part of the housing structure are made of different materials.

6. The method according to claim 5,
wherein before providing the housing structure, the first disconnected dams and the remaining part of the housing structure are formed in two different manufacturing processes.

7. The method according to claim 1,
wherein the second continuous dams are made of the same material which differs from the material of the first disconnected dams or is identical to the material of the first disconnected dams.

8. The method according to claim 1,
wherein the first disconnected dams and the second continuous dams are directly adjacent to each other but do not overlap each other.

9. The method according to claim 1,
wherein in lateral directions, the housing structure surrounds a lead frame structure which is configured for electrically contacting the plurality of semiconductor chips, and
in vertical direction, the housing structure is arranged in places on the lead frame structure and partially covers a front side of the lead frame structure, wherein a rear side of the lead frame structure is not covered by the housing structure.

10. The method according to claim 1,
wherein each of the semiconductor chips are electrically connected to a wiring structure, the wiring structure being covered by the second continuous dams but not by the first disconnected dams.

11. The method according to claim 1,
wherein
the optoelectronic components are singulated along singulating lines throughout the first disconnected dams and/or throughout the second continuous dams, and
each of the optoelectronic components has a hybrid reflector surrounding one of the semiconductor chips, the hybrid reflector being formed by singulated parts of the first disconnected dams and of the second continuous dams.

12. An optoelectronic component comprising a semiconductor chip, a housing and a hybrid reflector, wherein
the semiconductor chip is arranged in an opening of the housing,
the hybrid reflector vertically projects beyond the semiconductor chip and in a top view surrounds the semiconductor chip,
the hybrid reflector comprises two first opposite sidewalls and two second opposite sidewalls, wherein the first sidewalls directly adjoin the second sidewalls at interfaces which are formed exclusively by overlapping regions of inner side surfaces of the first sidewalls and of the second sidewalls, and
the first sidewalls are elevated parts of the housing and are made of a material different from a material of the second sidewalls.

13. (canceled)

14. The optoelectronic component according to claim 12,
which is a Quad Flat No-Leady (QFN) optoelectronic component, whose side surfaces are formed at least partly by side surfaces of the housing, wherein the optoelectronic component is free of electrical connections or pins projecting laterally beyond the side surfaces of the housing.

15. The optoelectronic component according to claim 12, comprising side surfaces which are formed partly by side surfaces of the housing and partly by outer side surfaces of the first sidewalls and of the second sidewalls, wherein the side surfaces of the housing and the outer side surfaces of the sidewalls show singulating traces.

16. The optoelectronic component according to claim 12, wherein the first sidewalls and remaining part of the housing are formed in one piece and are made of the same material.

17. The optoelectronic component according to claim 12, wherein the first sidewalls are arranged on remaining part of the housing, wherein the material of the first sidewalls differs from a material of the remaining part of the housing.

18. The optoelectronic component according to claim 12, further comprising a lead frame, wherein
the lead frame comprises a first subregion and a second subregion, the first and second subregions being assigned to different electrical polarities of the optoelectronic component,
the semiconductor chip is arranged on the first subregion of the lead frame,
the semiconductor chip is electrically connected to the second subregion by a wiring connection, and
the wiring connection is partly embedded within one of the second sidewalls.

19. The optoelectronic component according to claim 18,
which is formed as a surface-mountable device, wherein the optoelectronic component is externally electrically contactable at its rear side, where the first and second subregions of the lead frame are not covered by a material of the housing.

20. The optoelectronic component according to claim 12, wherein
the semiconductor chip is laterally surrounded by a reflective layer,
in a plan view of a front side of the component, the reflective layer is arranged between the semiconductor chip and the housing, and
in a plan view of a front side of the component, the reflective layer is partially covered by the second sidewalls but is not covered by the first sidewalls of the hybrid reflector.
